(19) United States
(12) Patent Application Publication
(10) Pub. No.: US 2025/0308909 A1
(43) Pub. Date: Oct. 2, 2025

(54) METHOD OF MAKING SILICIDE IN HIGH-ASPECT RATIO STRUCTURES BY H-RADICAL ASSISTED PROCESSES

(71) Applicant: Applied Materials, Inc., Santa Clara, CA (US)

(72) Inventors: Ying-Bing JIANG, Woodland, CA (US); In Seok HWANG, Pleassanton, CA (US); Zhijun CHEN, San Jose, CA (US); Avgerinos V. GELATOS, Scotts Valley, CA (US); Joung Joo LEE, San Jose, CA (US); Xianmin TANG, San Jose, CA (US); Yang HU, Santa Clara, CA (US); Thomas EMPANTE, Santa Clara, CA (US)

(21) Appl. No.: 18/623,546

(22) Filed: Apr. 1, 2024

(51) Int. Cl. H01L 21/285; H01L 21/02; H01L 21/768

(52) U.S. Cl. CPC H01L 21/28518; H01L 21/02301; H01L 21/76829

(57) ABSTRACT

Embodiments of the disclosure provided herein include methods of making silicide in high-aspect ratio structures by hybrid processes. The method includes selectively depositing a first metal layer in a plurality of structures formed in a multi-material layer stack including a repeating stack of an oxide-nitride-silicon-nitride (ONPN) layers. The method also includes treating the surface of the selectively deposited first metal layer formed in the plurality of structures by delivering a treatment gas containing hydrogen to the surface of the structure for a third period of time. A second metal layer is selectively deposited in the plurality of structures formed in the substrate.

### BACKGROUND

### Field

Embodiments described herein generally relate to semiconductor device fabrication, and more particularly, to systems and methods of forming bit lines in three-dimensional dynamic random-access memory devices.

### Description of the Related Art

Three-dimensional (3D) dynamic random-access memory (DRAM) devices pose challenges in manufacturability due to their three-dimensional (3D) designs and small sizes. Individual memory cells, each of which includes a field-effect transistor (FET) device, need to be connected to a bit line at the source/drain regions of the FET device. Fabrication of such bit lines typically requires line-of-sight processing and multiple process steps including a high-aspect-ratio (HAR) etching process to form slots for bit lines. For example, a 3D DRAM device may include alternating layers of silicon-based layers (P), oxide (O), and nitride (N). In some configurations of the 3D DRAM structure the silicon-based layers (e.g., Si or poly-Si) are selectively recessed, while in some other configurations the silicon-based layers are exposed in the vertical bit-line openings. In a 3D memory structure, such as 3D DRAM, silicide contacts are needed to be formed on the exposed portions of the silicon-based layers formed on the sidewalls of the deep HAR holes or deep HAR trenches. Conventional deposition techniques typically form the silicide layers at one specific and optimized dep-condition, but the species concentration gradient developed during transport in the deep holes/trenches will inherently cause non-uniformity of deposition. This conventional approach for forming the silicide layers in the vertical bit line features results in variations in the silicide layer properties which, among other things, leads to variations in the electrical characteristics of the 3D DRAM device.

Thus, there is a need for systems and methods that can fabricate vertical bit lines in a 3D DRAM device that solves the problems described herein.

### SUMMARY

Embodiments described herein generally relate to methods of making silicide in high-aspect ratio structures by hybrid processes.

In an embodiment, a method of forming a device is provided. The method includes selectively depositing a first metal layer in a plurality of structures formed in a multi-material layer stack formed on a substrate. The multi-material layer stack includes a repeating stack of an oxide-nitride-silicon-nitride (ONPN) layers, and the selectively depositing the first metal layer in the plurality of structures includes depositing the first metal layer on a surface of the silicon (P) containing layers of the ONPN layers exposed in the plurality of structures. Depositing the first metal layer includes delivering a first precursor gas to a surface of a substrate disposed in a processing region of a first processing chamber for a first period of time, purging the processing region of the processing chamber for a second period of time, and repeating. The method also includes treating the surface of the selectively deposited first metal layer formed in the plurality of structures. Treating the surface of the selectively deposited first metal layer includes delivering a treatment gas containing hydrogen to the surface of the structure for a third period of time. A second metal layer is selectively deposited in the plurality of structures formed in the substrate, and includes depositing the second metal layer over the surface of the deposited first metal layer. Selectively depositing the second metal layer includes delivering a second precursor gas to the surface of the substrate disposed in the processing region of the first processing chamber for a fourth period of time, purging the processing region of the first processing chamber for a fifth period of time, and repeating.

In another embodiment, a method of forming a device is provided. The method includes selectively depositing a first metal layer in a plurality of structures formed in a multi-material layer stack including a repeating stack of an oxide-nitride-silicon-nitride (ONPN) layers formed on a substrate. Selectively depositing the first metal layer in the plurality of structures includes depositing the first metal layer on a surface of the silicon (P) containing layers of the ONPN layers exposed in the plurality of structures. Depositing the first metal layer includes delivering a first precursor gas to a surface of a substrate disposed in a processing region of a first processing chamber for a first period of time, purging the processing region of the processing chamber for a second period of time, and repeating. The method also includes treating the surface of the selectively deposited first metal layer formed in the plurality of structures in a second processing chamber. Treating the surface of the selectively deposited first metal layer includes delivering a hydrogen radical gas to the surface of the substrate for a third period of time. A second metal layer is selectively deposited in the plurality of structures formed in the substrate, and includes depositing the second metal layer over the surface of the deposited first metal layer. Selectively depositing the second metal layer includes delivering a second precursor gas to the surface of the substrate disposed in a processing region of third processing chamber for a fourth period of time, purging the processing region of the third processing chamber for a fifth period of time, and repeating.

In yet another embodiment, a method of forming a device is provided. The method includes selectively depositing a first metal layer in a vertical channel on a surface of a silicon (P) layer of a multi-layer stack formed on a substrate. Depositing the first metal layer includes delivering a first precursor gas including molybdenum pentachloride to the surface of the P layer disposed in a processing region of a first processing chamber for a first period of time, and purging the first precursor gas from the processing region of the processing chamber for a second period of time. The method also includes exposing the surface of the selectively deposited first metal layer formed in a plurality of structures in a second processing chamber to a treatment gas including a hydrogen plasma to the surface of the substrate for a third period of time, and forming a metal cap on the first metal layer.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, may admit to other equally effective embodiments.

FIG. 1 illustrates a schematic, cross-sectional view of a structure, according to certain embodiments.

FIG. 2 shows a flow chart for a method of forming a structure according to certain embodiments.

FIG. 3 illustrates a memory structure undergoing the method of FIG. 2, according to certain embodiments.

FIG. 4A-4N illustrate iterative selective deposition processes, according to certain embodiments.

FIG. 4O illustrates iterative selective deposition processes, according to certain embodiments.

FIG. 4P illustrates a hybrid process for producing silicides, according to certain embodiments.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

The present disclosure relates to a method of selectively forming a silicide in high-aspect ratio structures by use of a H-radical assisted, multistep deposition process, which is often referred to herein as a hybrid deposition process.

In a three-dimensional memory structure, such as 3D DRAM, metal silicide contacts are formed on exposed portions of the silicon-based (P) layers in the sidewalls of the deep high aspect ratio holes or deep high aspect ratio trenches. Deposition techniques typically form the silicide layers at a specific deposition condition, but the halide species concentration gradient developed during transport in the deep holes/trenches will inherently cause non-uniformity of deposition. This conventional approach for forming the silicide layers in the vertical bit line features results in variations in the silicide layer properties which, among other things, leads to variations in the electrical characteristics of the memory structure.

The present disclosure provides for methods for producing high aspect ratio structures with lateral contacts having uniform thicknesses by introducing an intermittent treatment process to reduce halide contamination in the P layers of the memory structures. The halide contamination being created during the deposition and formation of a silicide layer on the P layers, due to the exposure to a metal halide precursor, such as molybdenum pentachloride (MoCl₅), tungsten hexachloride (WCl₆) or titanium tetrachloride (TiCl₄) precursor. The intermittent treatment process includes the use of a hydrogen radical or hydrogen plasma irradiation on the growing surface, e.g., the surface of the P layers, periodically. The treatment process, ideally performed in a secondary processing chamber, reduces in halide contamination in the Players, resulting in improved metal silicide coverage over deep and high aspect ratio features.

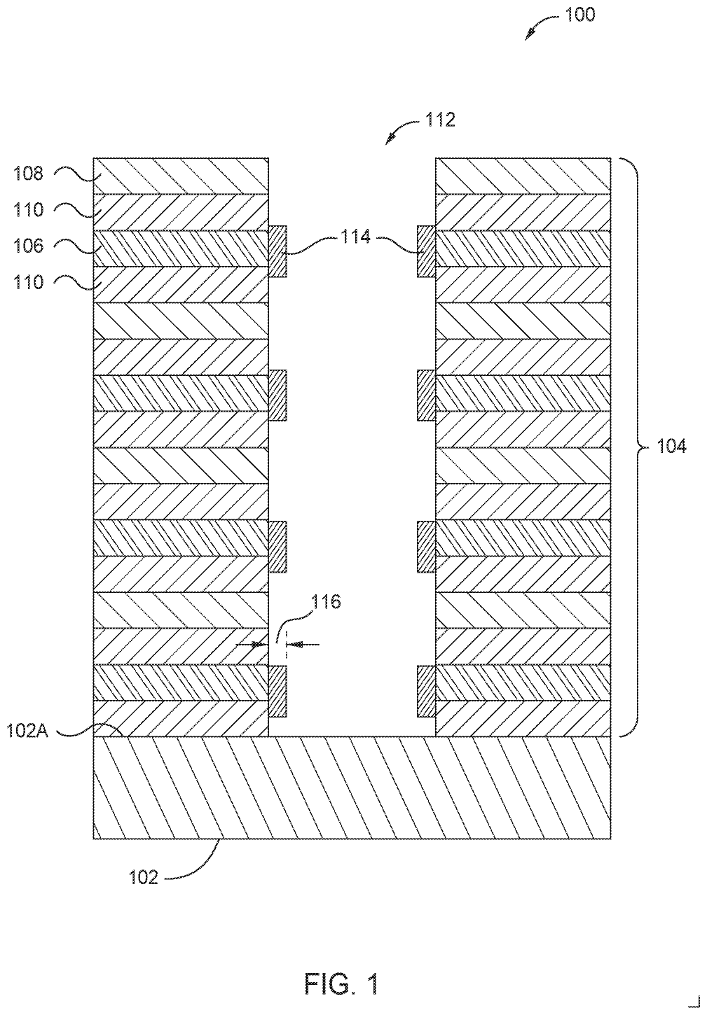

FIG. 1 shows a schematic, cross-sectional view of a memory structure 100, according to certain embodiments. The memory structure 100 includes a substrate 102 and a multi-layer stack 104 deposited on a top surface 102A of the substrate 102. The multi-layer stack 104 includes alternating P layers 106, O layers 108, and N layers 110. A vertical channel 112 is formed through the multi-layer stack 104 to create the memory structure 100, such as a 3D DRAM or 3D NAND memory structure.

The multi-layer stack 104 includes a plurality of native oxide layers covering a silicon-based P layer of a memory structure 100. The memory structure 100 includes a plurality of vertical channels 112 through the multi-layer stack 104 to the top surface 102A of the substrate 102. Alternatively, the vertical channels 112 may extend only through a portion of the multi-layer stack 104, e.g., the top surface 102A of the substrate 102 remains under the vertical channel 112. The multi-layer stack 104 may include multiple repeating layers, such as a four layer stack of an O layer, N layer, P layer, and N layer, e.g., oxide-nitride-silicon-nitride layers, which is referred to herein as ONPN layers. In one example, the ONPN layers include an oxide layer 108 (e.g., SiOₓ), a first nitride layer 110 (e.g., silicon nitride (SiₓN_{y})), a silicon layer 106 (e.g., polysilicon, a-silicon, c-silicon), and a second nitride layer 110 (e.g., silicon nitride (SiₓN_{y})). In one example, the ONPN layer stack includes silicon oxide (SiOₓ), silicon nitride (SiₓN_{y}), polysilicon (poly-Si), and silicon nitride (SiₓN_{y}). The channels may have a depth of about 2 μm to about 8 μm, such as about 2 μm, about 3 μm, about 4 μm, about 5 μm, about 6 μm, or the like. The channels may include an aspect ratio of about 1:8 to about 1:160, e.g., about 1:8, about 1:10, about 1:50, about 1:100, about 1:150, about 1:160; or the like.

The memory structure 100 includes a plurality of lateral contacts 114 deposited within the vertical channels 112 at a surface of each of the Players 106, e.g., the silicon layers, of the multi-layer stack 104 on either side of each vertical channel 112. The lateral contacts 114 include a metal, e.g., molybdenum, titanium, alloys, or combinations thereof, and have a thickness 116. The lateral contacts 114 are deposited after the formation of the vertical channels 112 in the multi-layer stack 104.

Due to the high aspect ratio of the vertical channels 112, the lateral contacts 114 near the top of the memory structure 100 need to be etched away at increased deposition cycle numbers to ensure deposition near the bottom of the memory structure 100. This results, however, in the plurality of lateral contacts 114 to have a gradient or non-uniform thickness throughout the vertical channel 112, e.g., the lateral contacts 114 near the top of the memory structure 100 to have a smaller thickness than the lateral contacts 114 near the bottom of the memory structure 100. Similarly, if etching does not occur, the lateral contacts 114 near the top of the vertical channel 112 will create a bottleneck creating a pinch-off point, e.g., deposition will occur mostly near the top of the vertical channels 112 leading to increased thicknesses of the lateral contacts 114, that prevents adequate deposition of metal to the lateral contacts 114 near the bottom of the vertical channel 112. This, again, results in a gradient or non-uniform thickness throughout the vertical channel 112.

Additionally, there may also be a buildup of chloride (Cl—) species, particularly on the P layers 106, from the metal deposition process which often uses chloride as a precursor component required for deposition, e.g., molybdenum pentachloride (MoCl₅). When the silicon of a P layer 106 is exposed to MoCl₅, the molybdenum binds to the silicon to create molybdenum silicide (MoSi) while also producing silicon chloride (SiCl₄). In a subsequent exposure, or even during the same exposure, to MoCl₅, chlorine diffuses through the MoSi and molybdenum layers to bind to the silicon of the P layer 106. This diffusion creates a chloride accumulation at the silicon-molybdenum silicide interface, preventing further molybdenum deposition. Lower operating temperatures may further increase chloride accumulation in the P layer 106. The chloride buildup may be exacerbated if the P layers 106 are recessed into the multi-layer stack 104, e.g., each of the adjacent N layers 110 overhang the P layer 106 (not shown). This chloride buildup prevents silicon uptake to the growing silicide surface, thereby consuming the metal, e.g., molybdenum or molybdenum silicide, causing the lateral contacts 114 to deposit with a non-uniform thickness. The non-uniform thickness of the plurality of lateral contacts 114 may undesirably affect the performance of the memory structure 100, e.g., making the memory structure 100 performance unpredictable.

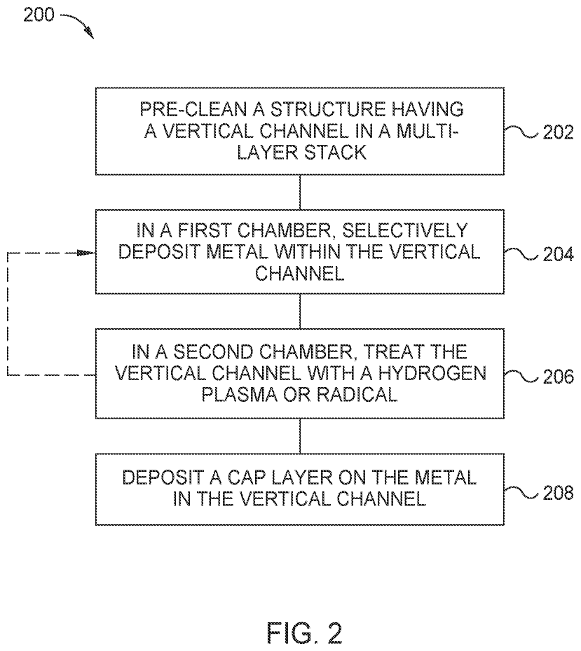

FIG. 2 shows a flow chart for a method 200 of forming a memory structure 100, specifically forming lateral contacts 114 in a vertical channel 112, according to certain embodiments. FIG. 3 illustrates a memory structure 100, similar to the memory structure 100 of FIG. 1, undergoing the method of FIG. 2, according to certain embodiments.

The method 200 includes using a cleaning process 302 on the memory structure 100 in operation 202 to remove a native oxide formed on the P layer 106, either by a wet etch or dry etch processes. The wet etch process may include exposing the vertical channels 112 of the memory structure 100 to a cleaning solution, such as dilute hydrofluoric acid (d-HF), to etch the native oxide layer from the P layer 106. A dry etch process may include exposing the vertical channels 112 of the memory structure 100 to cleaning gases. The cleaning gases may include a nitrogen-containing gas, such as NH₃, and a fluorine-containing gas, such as HF, flowed either in combination or in sequence. For example, the dry etch process may include exposing the vertical channels 112 to an NH₃ gas before exposing the vertical channels 112 to an HF gas. Alternatively, the NH₃ gas and the HF gas may be co-flowed. The dry etch process may be performed at a pressure of about 400 mTorr to about 600 mTorr, such as about 450 mTorr to about 550 mTorr, such as about 500 mTorr.

In operation 204, the method 200 includes performing a first selective deposition process 304. The first selective deposition process 304 is performed in a processing region of a deposition chamber (not shown), such as chemical vapor deposition (CVD) chamber or a plasma enhanced CVD chamber, available from Applied Materials Inc. The first selective deposition process 304 includes dosing the cleaned memory structure 100 with a precursor gas that includes a metal species, such as a metal halide including molybdenum, tungsten, or titanium, or a combination thereof. In one example, the metal species may include molybdenum pentachloride (MoCl₅). The metal species may include titanium tetrachloride (TiCl₄). The dose is applied for about 2 second or more to about 7 second or less, such as about 2 seconds, 3 seconds, 4 seconds, 5 seconds, 6 seconds, 7 seconds, and the like. For example, and without limitation, the dose may be applied for less than 2 seconds. As a further non-limiting example, the dose may be applied for about 2 seconds to about 3 seconds, e.g., about 2.1 seconds, about 2.2 seconds, about 2.3 seconds, about 2.4 seconds, about 2.5 seconds, about 2.6 seconds, about 2.7 seconds, about 2.8 seconds, about 2.9 seconds, about 3.0 seconds, or the like.

The first selective deposition process 304 includes a first temperature. Without wishing to be bound by theory the temperature of the substrate 102 during processing may influence the location of the deposition process within the vertical channels 112 formed in the multilayer stack. For example, a high temperature, e.g., greater than about 380° C., may provide better efficiency of depositing the metal species towards a top section of the vertical channels 112, whereas a low temperature, e.g., less than about 350° C., may provide better efficiency of depositing the metal species towards a bottom section of the vertical channels 112. The first temperature is a high temperature, in which the first temperature is greater than about 350° C., such as greater than about 380° C.

The first selective deposition process 304 includes a first pressure. Without wishing to be bound by theory the pressure of the chamber may influence the location of the deposition process within the vertical channels 112. For example, a pressure, e.g., greater than about 10 Torr, may provide better efficiency of depositing the metal species towards a top section of the vertical channels 112, whereas a low pressure, e.g., less than about 10 Torr, may provide better efficiency of depositing the metal species towards a bottom section of the vertical channels 112. The first pressure is a high pressure, in which the first pressure is greater than about 20 Torr.

The first selective deposition process 304 may be repeated, which may allow proper calibration of the delivery of the precursor over the surface of the substrate 102 and removing the residual chlorinated species. A certain number of cycles of the first selective treatment may be carried out, e.g., about 2 cycles to about 300 cycles, about 5 to about 10 cycles, about 50 to about 300 cycles, about 5 to 50 cycles, about 50 to about 300 cycles, and the like. All or some of the first selective deposition process 304 may be cycled to achieve a targeted deposition result.

In operation 206, the method 200 includes performing a treatment process 306. During the treatment process 306, the first selective deposition process 304 is paused. The treatment process 306, or layer modification process, includes exposing the memory structure 100 surface, including the vertical channels 112, to a treatment gas. The treatment gas may include a hydrogen gas or a hydrogen containing plasma. A hydrogen gas may include hydrogen radical species, which are capable of removing the chlorinated species that may have accumulated in or at a surface of the Players 106. In one non-limiting example, the treatment process 306 is performed in a second process chamber, which is different from the first process chamber in which the cyclic selective metal deposition process is performed. In one example, the second process chamber is also a CVD chamber. The second process chamber will generally not include or have been exposed to the metal halide precursors. Alternatively, the treatment process 306 may be performed in the first process chamber by purging the metal halides from the first chamber before exposing the memory structure 100 to the treatment gas. In such embodiments, the treatment gas is purged from the first chamber before resuming further cycles of the first deposition process.

In one embodiment, exposing the memory structure 100 to the hydrogen radicals includes directing hydrogen radical species towards the memory structure 100, to remove the one or more of the chlorinated species that are disposed on or within the vertical channels 112 of the memory structure 100. The hydrogen radicals can be formed in a remote plasma source (RPS) coupled to the processing region of the processing chamber (e.g., second CVD chamber). The removal process may be effective to remove the one or more chlorinated species from the surface of the P layers 106 of the multi-layer stack 104. In one or more embodiments, removed chlorinated species are then purged from the secondary chamber.

The treatment process 306 may proceed according to one of a set of sub-operations. In a first sub-operation, the treatment process 306 begins after the first selective deposition process 304. The treatment process 306 begins early, e.g., after about 100 to about 300 cycles of the first selective deposition process 304, such as after about 200 cycles of the first selective deposition process 304. The treatment process 306 is applied for a duration of time, after which the first selective deposition process 304 is restarted. The duration of time for the treatment process 306 may be about 120 seconds or more to about 15 seconds of less, e.g., about 90 second to about 30 seconds, about 75 seconds to about 45 seconds, about 60 second, and the like. The first sub-operation results in less consumption of the silicon in the P layers 106, preserving the P layer 106. This may be preferred in embodiments where the P layer 106 is recessed or where P layer 106 thickness is critical.

In a second sub-operation, the treatment process 306 begins after the first selective deposition process 304. The treatment process 306 begins, e.g., after about 200 to about 400 cycles of the first selective deposition process 304, such as after about 250 cycles of the first selective deposition process 304. The treatment process 306 is applied for a duration of time, after which the selective deposition process is restarted. The duration of time for the treatment process 306 may be about 120 seconds or more to about 15 seconds of less, e.g., about 90 second to about 30 seconds, about 75 seconds to about 45 seconds, about 60 second, and the like. By starting the treatment process 306 after about 250 cycles of the first selective deposition process 304, there may be a broad processing window which allows for additional tailoring of the procedure.

In one implementation of a third sub-operation, the treatment process 306 begins after the first selective deposition process 304. The treatment process 306 begins, e.g., after about 100 to about 300 cycles of the first selective deposition process 304, such as after about 200 cycles of the first selective deposition process 304. The treatment process 306 is applied for a duration of time, after which the first selective deposition process 304 is restarted. The duration of time for the treatment process 306 may be about 120 seconds or more to about 15 seconds of less, e.g., about 90 second to about 30 seconds, about 75 seconds to about 45 seconds, about 60 second, and the like. During this implementation of the third sub-operation, the application of the hydrogen radical gas to the memory structure 100 is pulsed during the treatment process 306 to enhance the consumption of silicates. In one non-limiting example, the hydrogen radical gas is applied for about 5 second to about 15 seconds, such as about 7 seconds to about 13 seconds, about 8 seconds, about 9 seconds, about 10 seconds, about 11 second, about 12 seconds, and the like. Application of the hydrogen radical gas is then suspended for a duration of e.g., about 5 second to about 15 seconds, such as about 7 seconds to about 13 seconds, about 8 seconds, about 9 seconds, about 10 seconds, about 11 second, about 12 seconds, and the like. Application of the hydrogen radical gas is then restarted, and the hydrogen radical gas is applied for about 5 second to about 15 seconds, such as about 7 seconds to about 13 seconds, about 8 seconds, about 9 seconds, about 10 seconds, about 11 second, about 12 seconds, and the like. Pulsing the treatment gas as described in the third sub-operation also reduces silicon consumption in the Players 106, preserving the P layer 106 while improving metal deposition uniformity, e.g., thickness 116 of each lateral contact 114, within the vertical channels 112.

After the treatment process 306 of operation 206, the method 200 may optionally return to the first selective deposition process 304 of operation 204 for additional metal deposition. Following the optional metal deposition process, the memory structure 100 again undergoes the treatment process 306 of operation 206. Operations 204 and 206 are then repeated as desired. Once the desired cycles of operation 204 and 206 are completed, the memory structure 100 may optionally undergo a cap deposition process 308 in operation 208. The cap deposition process 308 may include a metal deposition process, such as an in situ atomic layer deposition (ALD) process, to deposit a metal cap 310, e.g. a titanium nitride cap, on the plurality of lateral contacts 114 in the vertical channels 112. The metal cap 310 acts as a diffusion barrier, preventing unwanted diffusion of elements between different layers of the memory structure 100. For example, a titanium nitride cap on lateral contacts 114 made of molybdenum prevent the molybdenum from reacting with dopant elements, such as boron or arsenic, in other parts of the memory structure 100. The metal cap 310 also improves adhesion between the plurality of lateral contacts 114 and a subsequent metal layer, e.g. tungsten or tungsten silicide, deposited in the vertical channels 112 on top of the lateral contacts 114.

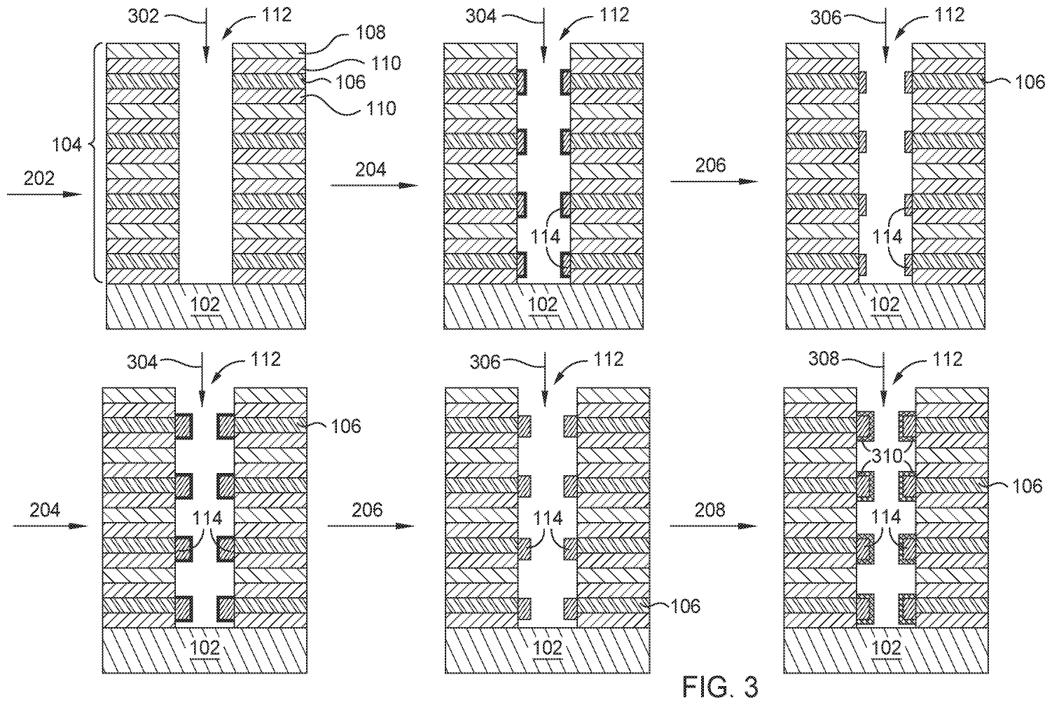

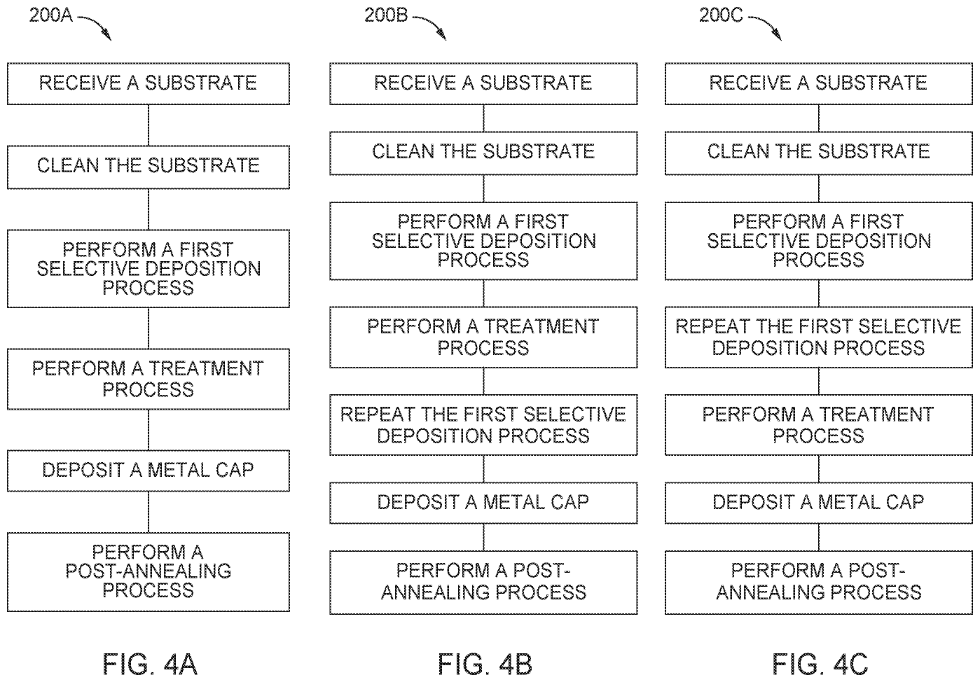

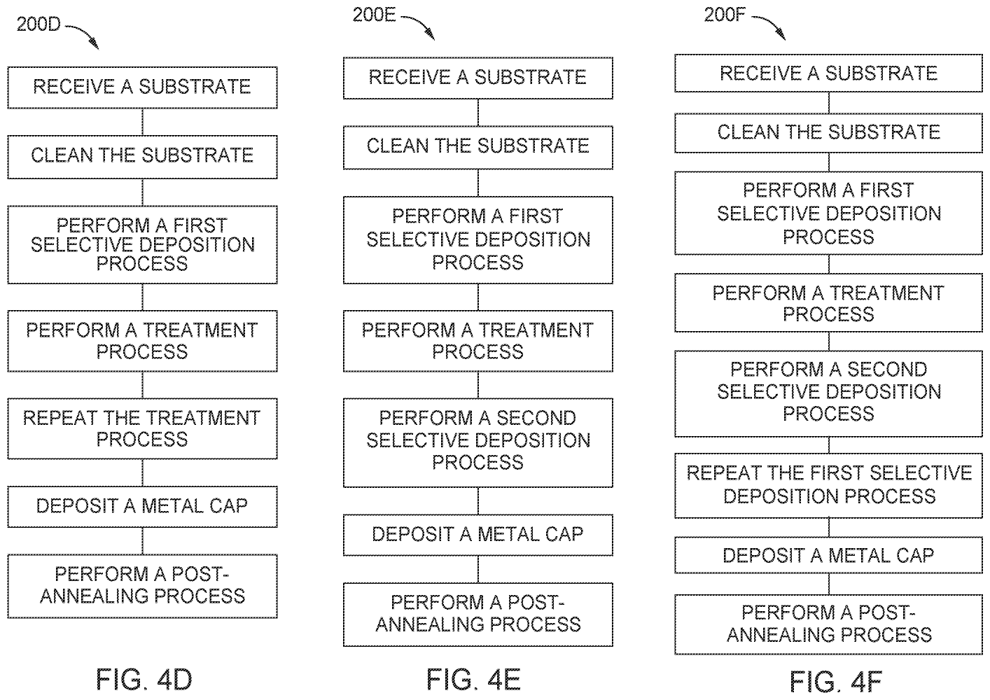

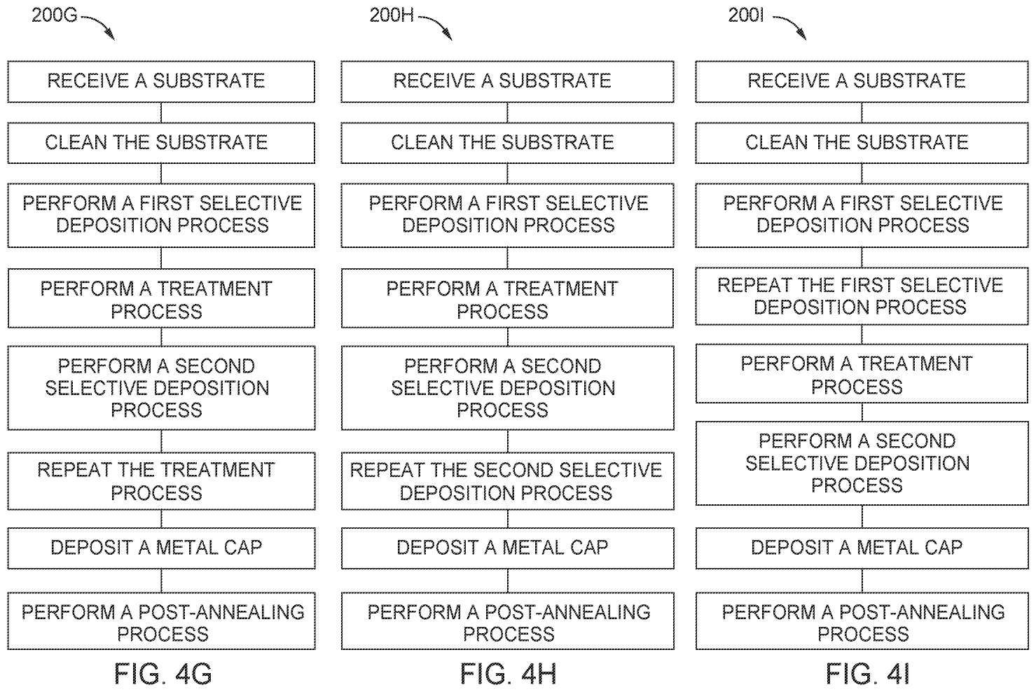

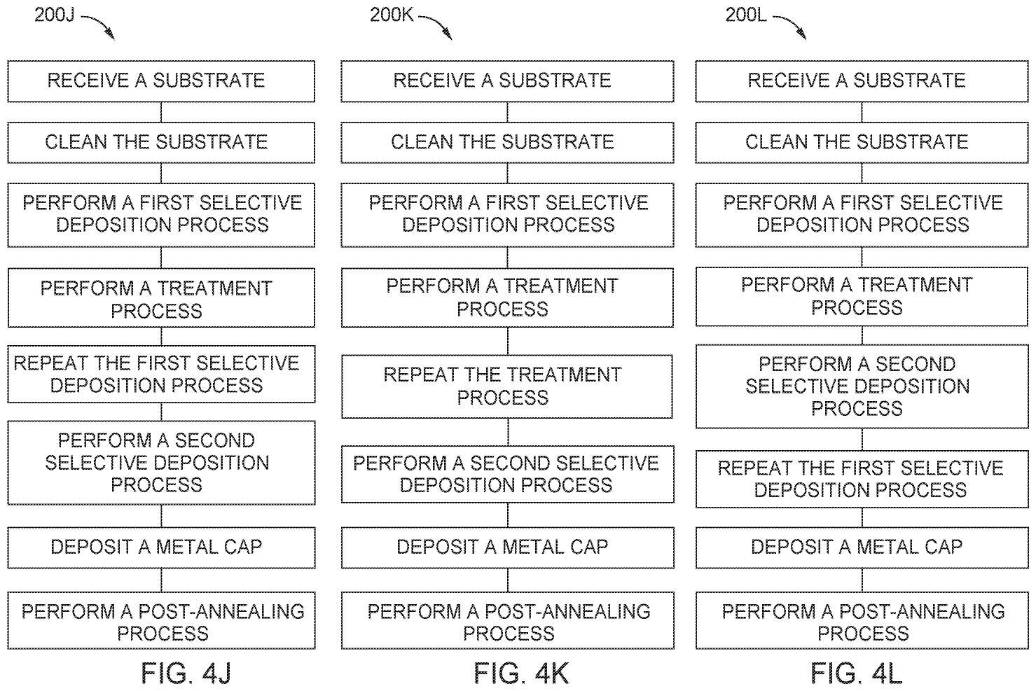

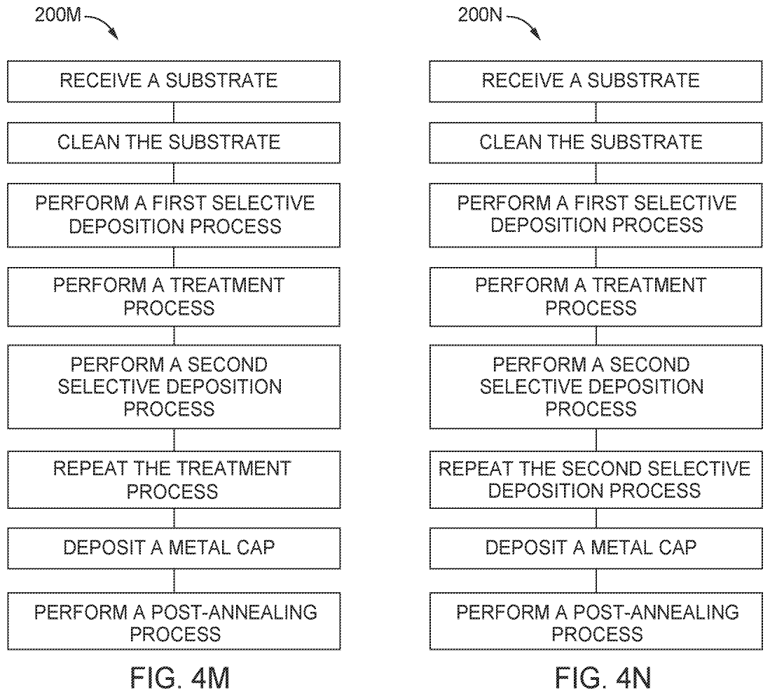

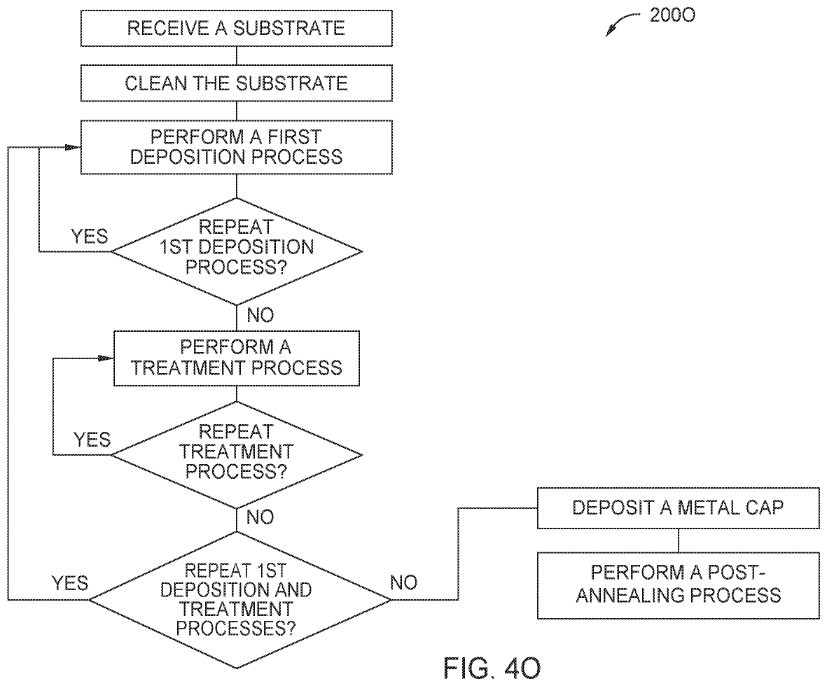

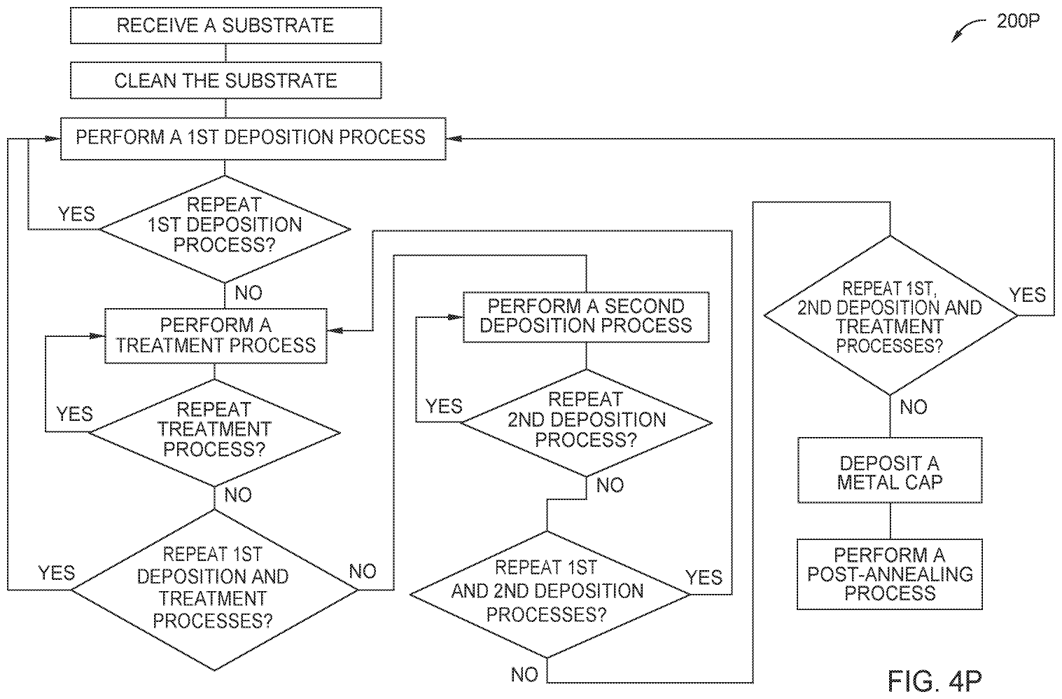

FIGS. 4A-4P illustrate select variations of the method 200 of FIG. 2, e.g. methods 200A-200P. The methods 200A-200P include performing a treatment process, as shown in FIGS. 4A-4P, after performing one or more first selective deposition processes (e.g., deposition process 304). The treatment process may be further understood with reference to FIGS. 2 and 3. During the treatment process, a hydrogen containing gas, such as a radical containing gas that comprises hydrogen radicals is applied to remove the chlorinated species from memory structure 100, as described above.

The methods 200E-200P may further include a second selective deposition process includes exposing the cleaned memory structure 100 with a precursor gas that includes a metal species, e.g., molybdenum chloride, titanium chloride, or the like, as described above. For example, the second selective deposition process may include a dose time of about 3 seconds, and a hydrogen radical exposure time of about 7 seconds.

The second selective deposition process includes a second temperature. In some embodiments, the second temperature is a low temperature, in which the second temperature is less than about 350° C. The second selective deposition process includes a second pressure. In some embodiments, the second pressure is a low pressure, in which the second pressure less than about 10 Torr. In one example, the second pressure is between 0.1 Torr and 10 Torr, such as between 0.5 Torr and 9 Torr.

In an embodiment, the methods 200A-200D include an iterative process that repeats one or more of the first selective deposition process and the treatment process, as shown in FIGS. 4A-4D. For example, and without limitation, an iterative process may include performing a first selective deposition process, a treatment process, and repeating the first selective deposition process. As a further non-limiting example, an iterative process may include performing a first selective deposition process, a treatment process, and repeating the treatment process. As a further non-limiting example, an iterative process may include performing a first selective deposition process, repeating the first selective deposition process, and performing a treatment process. In one example, a pressure, e.g., greater than about 10 Torr may be used during the first selective deposition process. The first pressure is a high pressure, in which the first pressure is greater than about 20 Torr.

In an embodiment, the methods 200E-200N include an iterative process that repeats one or more of the first selective deposition process, the treatment process, or one or more second selective deposition processes, as shown in FIGS. 4E-4N. For example, and without limitation, an iterative process may include performing a first selective deposition process, a treatment process, a second selective deposition process, and repeating the first selective deposition process. As a further non-limiting example, an iterative process may include performing a first selective deposition process, a treatment process, a second selective deposition process, and repeating the treatment process. As a further non-limiting example, an iterative process may include performing a first selective deposition process, a treatment process, a second selective deposition process, and repeating the second selective deposition process.

The repetition may be performed after the first selective deposition process, the treatment process, the second selective deposition process, or in between each of the processes, as shown in FIGS. 4G-4N. For example, and without limitation, the iterative process may include performing a first selective deposition process, repeating the first selective deposition process, and performing a treatment process followed by a second selective deposition process. As a further non-limiting example, the iterative process may include performing a first selective deposition process and a treatment process, repeating the first selective deposition process, and performing a second selective deposition process. As a further non-limiting example, the iterative process may include performing a first selective deposition process and a treatment process, repeating the treatment process, and performing a second selective deposition process. As a further non-limiting example, the iterative process may include performing a first selective deposition process, a treatment process, a second selective deposition process, and repeating the first selective deposition process. As a further non-limiting example, the iterative process may include performing a first selective deposition process, a treatment process, a second selective deposition process, and repeating the treatment process. As a further non-limiting example, the iterative process may include performing a first selective deposition process, a treatment process, a second selective deposition process, and repeating the second selective deposition process.

FIG. 4O illustrates an example of a two-process step method 2000 containing processing sequence in which one or more first selective deposition processes (P1) and one or more treatment processes (P2) can each be individually repeated zero to N times, where N is an integer greater than zero (e.g., 1, 2, 5, 10, 100, etc.), or interleaved in any desired sequence to form a deposited layer within a feature. Each of the processes in the process sequence will include at least one process variable that is different from a process variable within the other process sequences. In one example, the process variable is selected from a process pressure, temperature, deposition time, and ratio of deposition-to-hydrogen radical time. In one example, the processing sequence could include a sequence P1-P2-P1-P2 . . . . P1-P2. In another example, the processing sequence could include a sequence P1-P1-P2-P1-P1-P2. In yet another example, the processing sequence could include a sequence P1-P2-P2-P1-P2 . . . . P1-P2-P2-P1-P2.

FIG. 4P illustrates an example of a three-process step method 200P containing processing sequence in which one or more first selective deposition processes (P1), one or more treatment processes (P2) and one or more second selective deposition processes (P3) can each be individually repeated zero to N times, where N is an integer greater than zero (e.g., 1, 2, 5, 10, 100, etc.), or interleaved in any desired sequence to form a deposited layer within a feature. In one example, the processing sequence could include a sequence P1-P2-P3-P1-P2-P3 . . . . P1-P2-P3.

When introducing elements of the present disclosure or exemplary aspects or embodiments thereof, the articles “a,” “an,” “the” and “said” are intended to mean that there are one or more of the elements.

The terms “comprising,” “including” and “having” are intended to be inclusive and mean that there may be additional elements other than the listed elements.

The term “coupled” is used herein to refer to the direct or indirect coupling between two objects. For example, if object A physically touches object B and object B touches object C, the objects A and C may still be considered coupled to one another-even if objects A and C do not directly physically touch each other. For instance, a first object may be coupled to a second object even though the first object is never directly in physical contact with the second object.

While the foregoing is directed to embodiments of the present disclosure, other and further embodiments of the disclosure may be devised without departing from the basic scope thereof, and the scope thereof is determined by the claims that follow.

What is claimed is:

1. A method of forming a device, comprising:
selectively depositing a first metal layer in a plurality of structures formed in a multi-material layer stack formed on a substrate, wherein the multi-material layer stack comprises a repeating stack of an oxide-nitride-silicon-nitride (ONPN) layers, and the selectively depositing the first metal layer in the plurality of structures comprises depositing the first metal layer on a surface of the silicon (P) containing layers of the ONPN layers exposed in the plurality of structures, wherein depositing the first metal layer comprises:
(a) delivering a first precursor gas to a surface of a substrate disposed in a processing region of a first processing chamber for a first period of time;
(b) purging the processing region of the processing chamber for a second period of time; and
(c) repeating (a) and (b) at least one time;
treating the surface of the selectively deposited first metal layer formed in the plurality of structures, wherein treating the surface of the selectively deposited first metal layer comprises delivering a treatment gas containing hydrogen to the surface of the structure for a third period of time; and
selectively depositing a second metal layer in the plurality of structures formed in the substrate, and the selectively depositing the second metal layer comprises depositing the second metal layer over the surface of the deposited first metal layer, wherein selectively depositing the second metal layer comprises:
(a) delivering a second precursor gas to the surface of the substrate disposed in the processing region of the first processing chamber for a fourth period of time;
(b) purging the processing region of the first processing chamber for a fifth period of time; and
(c) repeating (a) and (b) at least one time.

2. The method of claim 1, further comprising forming a metal cap over the surface of the substrate after the fifth time period has elapsed.

3. The method of claim 2, wherein the metal cap comprises a titanium nitride (TiN).

4. The method of claim 1, further comprising cleaning the surface of the substrate before the first time period.

5. The method of claim 1, wherein the third time period is either greater than or less than the first time period, the fifth time period, or both the first time period and the second time period or the fourth time period and the fifth time period.

6. The method of claim 1, wherein the first precursor gas and the second precursor gas comprise molybdenum (Mo) or titanium (Ti).

7. The method of claim 1, wherein the first precursor gas and the second precursor gas further comprise chlorine (CI).

8. The method of claim 1, wherein the first precursor gas and the second precursor gas comprise titanium chloride.

9. The method of claim 1, wherein (a) and (b) are repeated between about 5 and about 300 times during the process of selectively depositing the first metal layer.

10. The method of claim 9, wherein (a) and (b) are repeated between about 5 and about 300 times during the process of selectively depositing the second metal layer.

11. The method of claim 1, wherein the S layer in the ONPN stack is a polysilicon containing layer.

12. The method of claim 11, wherein the O layer and the N layers in the ONPN stack are a silicon oxide layer and a silicon nitride layers, respectively.

13. The method of claim 1, wherein the time to complete the process of selectively depositing the second metal layer is about 60 seconds.

14. The method of claim 1, wherein delivering a hydrogen radical gas to the surface of the substrate during a third time period comprises pulsing the delivery of the hydrogen radical gas during the third time period.

15. The method of claim 14, wherein pulsing the delivery of the hydrogen radical gas during the third time period comprises pausing and resuming delivery of the hydrogen radical gas in a substantially cyclical manner during the third period of time.

16. The method of claim 1, wherein:
the treating the surface of the selectively deposited first metal layer formed in the plurality of structures comprises delivering a hydrogen radical gas to the surface of the substrate in a second processing chamber.

17. The method of claim 16, wherein the first process chamber is the same as or different from the second processing chamber.

18. A method of forming a device, comprising:
selectively depositing a first metal layer in a plurality of structures formed in a multi-material layer stack formed on a substrate, wherein the multi-material layer stack comprises a repeating stack of an oxide-nitride-silicon-nitride (ONPN) layers, and the selectively depositing the first metal layer in the plurality of structures comprises depositing the first metal layer on a surface of the silicon (P) containing layers of the ONPN layers exposed in the plurality of structures, wherein depositing the first metal layer comprises:
(a) delivering a first precursor gas to a surface of a substrate disposed in a processing region of a first processing chamber for a first period of time;
(b) purging the processing region of the processing chamber for a second period of time; and
(c) repeating (a) and (b) at least one time;
treating the surface of the selectively deposited first metal layer formed in the plurality of structures in a second processing chamber, wherein treating the surface of the selectively deposited first metal layer comprises delivering a hydrogen radical gas to the surface of the substrate for a third period of time; and
selectively depositing a second metal layer in the plurality of structures formed in the substrate, and the selectively depositing the second metal layer comprises depositing the second metal layer over the surface of the deposited first metal layer, wherein selectively depositing the second metal layer comprises:
(a) delivering a second precursor gas to the surface of the substrate disposed in a processing region of third processing chamber for a fourth period of time;
(b) purging the processing region of the third processing chamber for a fifth period of time; and
(c) repeating (a) and (b) at least one time.

19. The method of claim 18, wherein the first process chamber, the second processing chamber and the third processing chamber are the same processing chamber.

20. A method of forming a device, comprising:
selectively depositing a first metal layer in a vertical channel on a surface of a silicon (P) layer of a multi-layer stack formed on a substrate, wherein depositing the first metal layer comprises:
(a) delivering a first precursor gas comprising molybdenum pentachloride to the surface of the P layer disposed in a processing region of a first processing chamber for a first period of time; and
(b) purging the first precursor gas from the processing region of the processing chamber for a second period of time;
exposing the surface of the selectively deposited first metal layer formed in a plurality of structures in a second processing chamber to a treatment gas comprising a hydrogen plasma to the surface of the substrate for a third period of time; and
forming a metal cap on the first metal layer.
